(19) United States
(12) Patent Application Publication
(10) Pub. No.: US 2007/0195058 A1
(43) Pub. Date: Aug. 23, 2007

(54) Wireless cursor pointing device

(75) Inventor: Ying-Hung Lin, Taipei Hsien (TW)

Correspondence Address: BIRCH STEWART KOLASCH & BIRCH, PO BOX 747, FALLS CHURCH, VA, 22040-0747, US

(73) Assignee: BENQ CORPORATION

(21) Appl. No.: 11/705,437

(22) Filed: Feb. 13, 2007

(30) Foreign Application Priority Data
Feb. 14, 2006 (TW) 95104933

(51) Int. Cl. G09G 5/00; H03M 11/00; G08B 13/14; G06F 13/42

(52) U.S. Cl. 345/156; 340/572.1; 340/825; 341/22

(57) ABSTRACT

A wireless cursor pointing device is disclosed, the device including: an RFID transponder for sensing a radio frequency signal; and a switch connected to the RFID transponder for switching on and off the RFID transponder; wherein when the switch is switched on and the RFID transponder senses the radio frequency signal, the RFID transponder transmits a cursor signal.

### BACKGROUND OF THE INVENTION

1. Field of the Invention

The invention relates to a wireless cursor pointing device, and more particularly, to a wireless cursor pointing device without the need for a battery. The wireless cursor pointing device transmits a signal through a Radio Frequency Identification (RFID) system.

2. Description of the Prior Art

Please refer to FIG. 1 that shows the operation principle of the RFID, wherein an RFID reader 101 transmits a radio frequency signal and magnetic fields through an antenna 1011. An RFID transponder 102 receives (senses) the radio frequency signals and the magnetic fields through an antenna 1025 of a power supply circuit 1026, and thus generates an alternating current (AC). After the AC is rectified and filtered by a diode 1022, a capacitor 1023, and a capacitor 1024 in a regulator 1027, a direct current (DC) that can make an RFID chip 1021 work, is generated, so that the RFID reader 101 can communicate with the RFID transponder 102. The above is the operation principle of the RFID.

In addition, there has been a trend that a user makes a presentation through a computer as an assistant tool, which not only makes visual effect and sound effect, but also makes the content of the presentation more active and vivid, and makes the amendment of the presentation and the works easier. Because cord cursor pointing devices, for example cord mice and cord joysticks, have signal cables that are connected to computers, the movement of a user is limited by the cord cursor pointing devices. Therefore, the user may have a hard time trying to make a vivid presentation. In order to solve the above problem, there are wireless cursor pointing devices, for example, wireless mice, wireless joysticks, in the market, the wireless cursor pointing devices transmit signals through Bluetooth® or infrared light. However, batteries are necessary. Unfortunately these wireless cursor pointing devices with batteries still have the following disadvantages:

1. The ability to reduce the size of such wireless cursor pointing device is limited due to the volume of the batteries.

2. The batteries need to be re-charged to avoid depletion, which increases inconvenience.

3. The batteries must be replaced regularly, which adds more cost to the user.

4. The ingredients, for example, cadmium or mercury, of the batteries may pollute the environment when being discarded.

According to above disadvantages, developing an advanced product to solve out the disadvantages of the prior art is an important issue to people skilled in the art.

### SUMMARY OF THE INVENTION

In view of the above disadvantages, it is the object of the present invention to provide a wireless cursor pointing device without the need for a battery, so that the volume of the wireless cursor pointing device can be further reduced.

It is another object of the present invention to provide the wireless cursor pointing device without the need for a battery, so as to increase convenience in usability and reduce pollution to the environment.

In order to achieve the above objects, the wireless cursor pointing device disclosed in the present invention comprises:

an RFID transponder for sensing a radio frequency signal; and

a switch connected to the RFID transponder for switching on and off the RFID transponder; wherein when the switch is switched on and the RFID transponder senses the radio frequency signal, the RFID transponder transmits a cursor signal.

Moreover, the present invention discloses an electronic system having a wireless pointing device, the system comprising:

a host; an RFID reader connected to the host for transmitting a radio frequency signal; and a wireless cursor pointing device comprising an RFID transponder for sensing the radio frequency signal transmitted from the RFID reader, and transmitting a cursor signal; and a switch connected to the RFID transponder for switching on and off the RFID transponder, wherein when the switch is switched on, and the RFID transponder senses the radio frequency signal, the RFID transponder transmits the cursor signal, and the host performs a command according to the cursor signal.

The present invention discloses a transmission method for a wireless cursor pointing device having an RFID transponder that transmits a signal to a remote RFID reader, the method comprising the steps of: the RFID reader transmitting a radio frequency signal to the RFID transponder; switching on the RFID transponder to receive the radio frequency signal; and the RFID transponder transmitting a cursor signal to the RFID reader.

In a preferred embodiment of the present invention, the host is a computer, for example, a laptop computer or a desktop computer.

In another preferred embodiment of the present invention, the wireless cursor pointing device is a mouse.

In another preferred embodiment of the present invention, the wireless cursor pointing device is a keyboard.

In another preferred embodiment of the present invention, the RFID transponder includes a power supply circuit and a chip, the power supply circuit supplies power to the chip to generate the cursor signal.

In another preferred embodiment of the present invention, the power supply circuit includes an antenna that receives a magnetic field transmitted from the RFID reader and generates an AC for providing power to the power supply circuit.

In another preferred embodiment of the present invention, the power supply circuit further includes an antenna that receives a radio frequency signal transmitted from the RFID reader and through resonance generates an AC for providing power to the power supply circuit.

In another preferred embodiment of the present invention, the power supply circuit includes a voltage regulator for stabilizing power supplied to the chip.

In another preferred embodiment of the present invention, the switch is a press-type switch and the RFID transponder is switched on and off by pressing and releasing the switch.

In another preferred embodiment of the present invention, the button is a click button that is connected to the switch, and the switch is triggered when the click button is pressed, and the cursor signal generated by the RFID transponder corresponds to a click signal.

In another preferred embodiment of the present invention, the button is a selection button, and the switch is triggered when the selection button is pressed, and the cursor signal generated by the RFID transponder corresponds to a selection signal.

In another preferred embodiment of the present invention, the button is a direction control button, and the switch is triggered when the direction control button is pressed, and the cursor signal generated by the RFID transponder corresponds to a direction movement signal.

### BRIEF DESCRIPTION OF THE DRAWINGS

The present invention will now be specified with reference to its preferred embodiment illustrated in the drawings, in which

FIG. 1 is an electronic circuit of the RFID reader and RFID transponder of the prior art;

FIG. 2 is a system block diagram of the present invention;

FIG. 3 is a perspective view of the wireless cursor pointing device of the present invention;

FIG. 3A to 3C are disassembly views of the wireless cursor pointing device of the present invention;

FIG. 4A to 4C are electronic circuit diagrams of the RFID transponder, wherein the switch is installed in different positions and

FIG. 5 is a flowchart that shows the steps of the transmission method of the wireless cursor pointing device of the present invention.

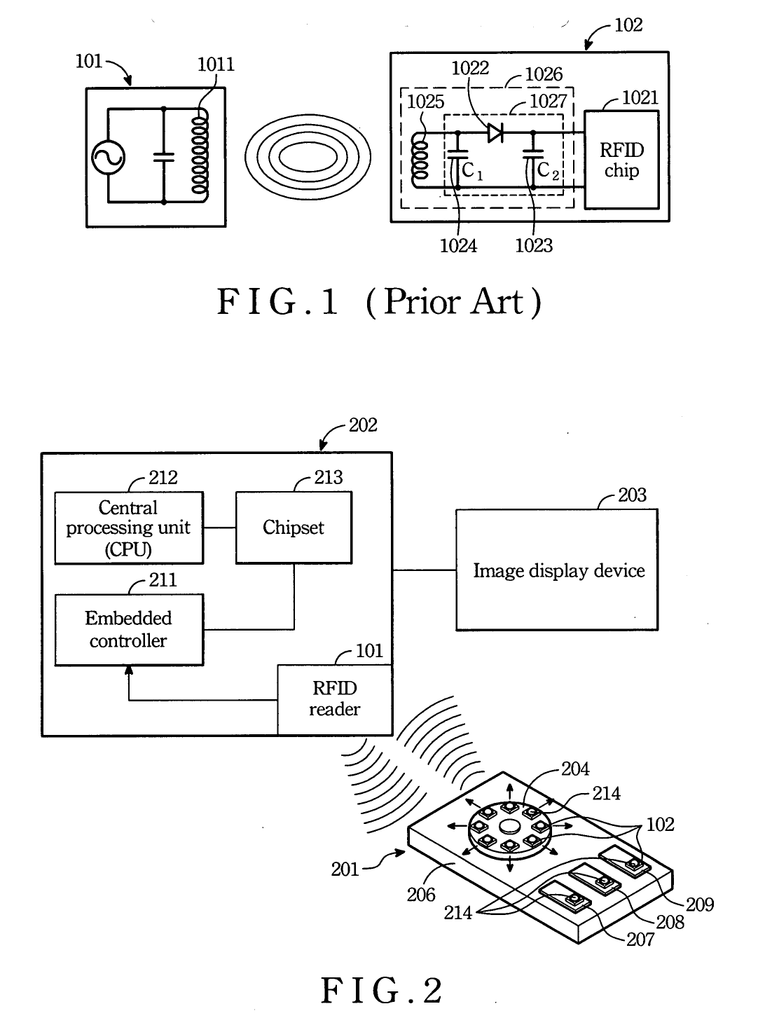

### DESCRIPTION OF THE PREFERRED EMBODIMENTS

Please refer to FIG. 2, which is a system block diagram of the present invention. The system block diagram of FIG. 2 includes: a host 202; an RFID reader 101 connected to the host 202 for transmitting a radio frequency signal; and a wireless cursor pointing device 201 comprising an RFID transponder 102 for sensing the radio frequency signal transmitted from the RFID reader 101, and transmitting a cursor signal; and a switch 214 connected to the RFID transponder 102 for switching on and off the RFID transponder, wherein when the switch 214 is switched on, and the RFID transponder 102 senses the radio frequency signal, the RFID transponder transmits the cursor correspondence signal, and the host performs a command according to the cursor signal.

The cursor pointing device 201 has a direction control button 204, at least one switch 214, at least one RFID transponder 102, a housing 206, a left button 207, a central button 208, and a right button 209. The direction control button is installed on the switch 214, and the switch 214 is electrically connected to the RFID transponder 102.

Since the RFID transponder 102 in the prior art is always “ON” to sense a radio frequency signal and a magnetic field transmitted from the RFID reader 101 of the host 202; hence, the switch 214 electrically connected to the RFID transponder 102 must be added in the preferred embodiment, so as to make the RFID transponder 102 be switched off, i.e., “OFF”; in other words, the RFID transponder 102 will not sense the radio frequency signal and the magnetic field transmitted from the RFID reader 101.

However, when the user presses the direction control button 204 to trigger the switch 214, then the RFID transponder 102 can sense the radio frequency signal and the magnetic field transmitted from the RFID reader 101, and transmits a cursor signal of the button to the RFID reader 101, so that the cursor on the image display device 203 has a correspondent movement. In another word, when the RFID transponder 102 senses the radio frequency signal, the RFID transponder 102 transmits the cursor signal, and the host performs a command according to the cursor signal.

Similarly, the preferred embodiment of the present invention has a left button 207, a central button 208, and a right button 209, which are the same as those of general mice. Therefore, there are a RFID transponder 102 and switch 214 respectively installed below each of the left button 207, the central button 208, and the right button 209.

Same as general mice, when the user presses the left button 207, that is, “click” the left button 207, the switch is triggered, so that the cursor signal of the RFID generates the click signal that is identical to clicking the button of the mice. Again, when the user presses the right button 209, the switch is triggered, so that the cursor signal of the RFID generates the selection signal that is identical to clicking the button of the mice.

The host 202 can be a laptop computer or desktop computer, which has the RFID reader 101, an embedded controller 211, a chipset 213, and a central processing unit (CPU) 212, the RFID reader 101 is electrically connected to the embedded controller 211, the embedded controller 211 is electrically connected to the chipset 213, and the chipset 213 is electrically connected to the CPU 212.

When the RFID reader 101 receives the cursor signal transmitted from the RFID transponder 102, then the RFID reader 101 may determine which one of the RFID transponders 102 generates the cursor signal, and the RFID reader 101 then transmits the cursor signal to the embedded controller 211 for processing. Hence the cursor signal is transmitted to the CPU 212 through the chipset 213. The CPU 212 transmits a command to the cursor on the image display device 203 to make the cursor move up, down, left, and right.

The image display device 203 can be a liquid crystal display (LCD), a cathode ray tube (CRT), or an organic light emitting diode (OLED) image display device, which is electrically connected to the host 202. It should be noted that if the host 202 is a laptop computer with a display device, the image display device 203 is not necessary, and the image can be displayed through the display device. The image display device 203 can display the cursor (not shown).

When the user presses the direction control button 204 of the cursor pointing device 201 for a certain time, then the CPU 212 of the host 202 starts processing, and the cursor on the image display device 203 may have the correspondent direction movement and correspondent movement distance. In other words, the user can easily press any direction of the direction control button 204 to determine the movement direction of the cursor on the image display device 203. At the same time, the time period of the user pressing the direction control button 204 of the cursor pointing device 201 can determine the movement distance of the cursor on the image display device 203.

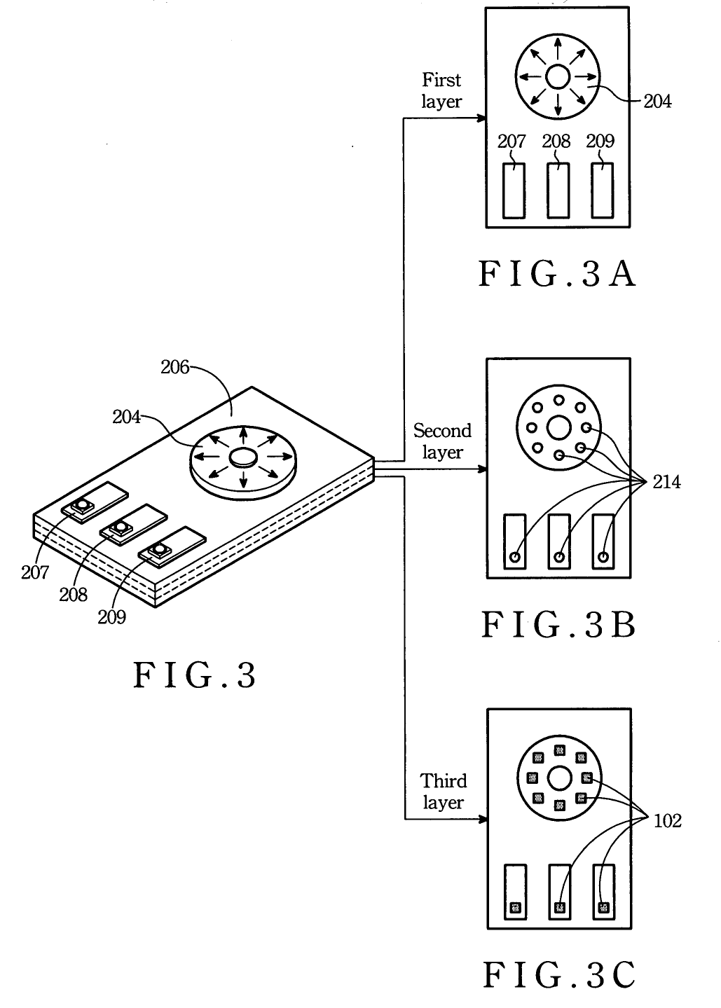

Please refer to FIG. 3, 3A, 3B and 3C, all of which respectively show perspective view and disassembly views of the wireless cursor pointing device of the present invention. The cursor pointing device includes: an RFID transponder 102 for sensing a radio frequency signal; and a switch 214 connected to the RFID transponder 102 for switching on and off the RFID transponder 102; wherein when the switch 214 is switched on and the RFID transponder senses the radio frequency signal, the RFID transponder transmits a cursor signal.

Please refer to FIG. 3A, 3B and 3C, all of which show the three-layer construction of the cursor pointing device 201, wherein a first layer has the direction control button 204, the left button 207, the central button 208, and the right button 209; a second layer has at least one switch 214 that is respectively installed below the direction control button 204, the left button 207, the central button 208, and the right button 209; a third layer has at least one RFID transponder 102 that is electrically connected to the switch 214.

As mentioned above, when the user presses any direction of the direction control button 204 to trigger the switch 214 through the direction control button 204, then the RFID transponder 102 can sense the radio frequency signal and the magnetic field transmitted from the RFID reader 101, and can transmit the cursor signal of the button to the RFID reader 101 to determine the movement direction of the cursor on the image display device 203. At the same time, the time period of the user pressing the direction control button 204 of the cursor pointing device 201 can determine the movement distance of the cursor on the image display device 203.

In addition, when the user presses the left button 207, that is, “click” the left button 207, then the switch is triggered, so that the RFID transponder 102 may generate a click signal of clicking the button. On the other hand, when the user presses the right button 209, the switch is triggered, so that the RFID transponder 102 may generate a selection signal of the selection button. The more the RFID transponders 102 of the direction control button 204 are, the more accurate direction the cursor on the image display device 203 can move.

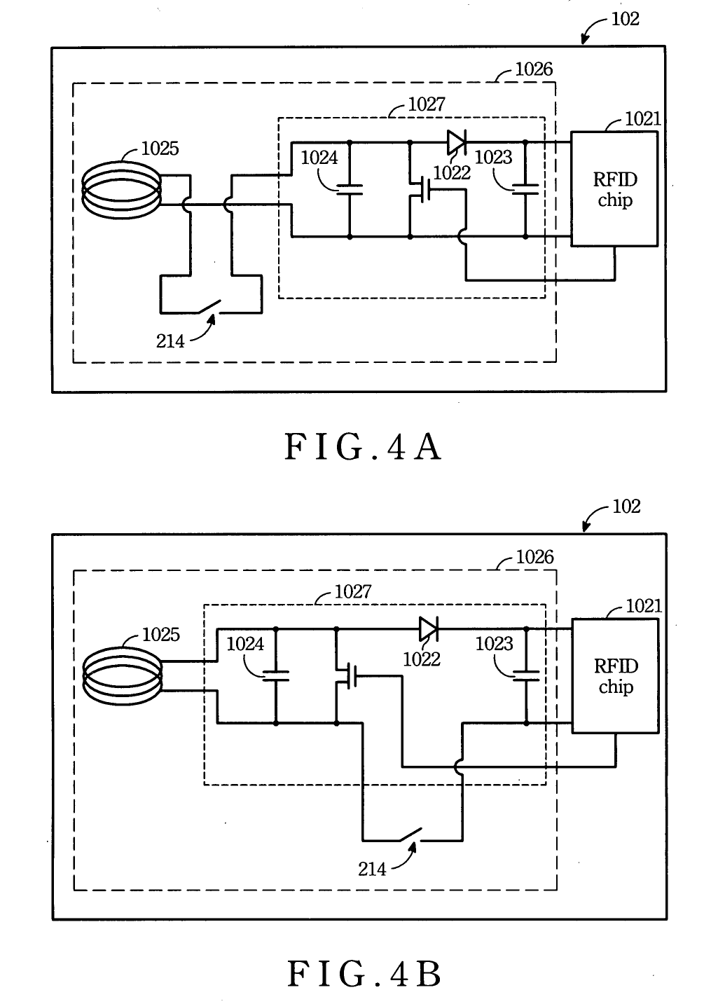

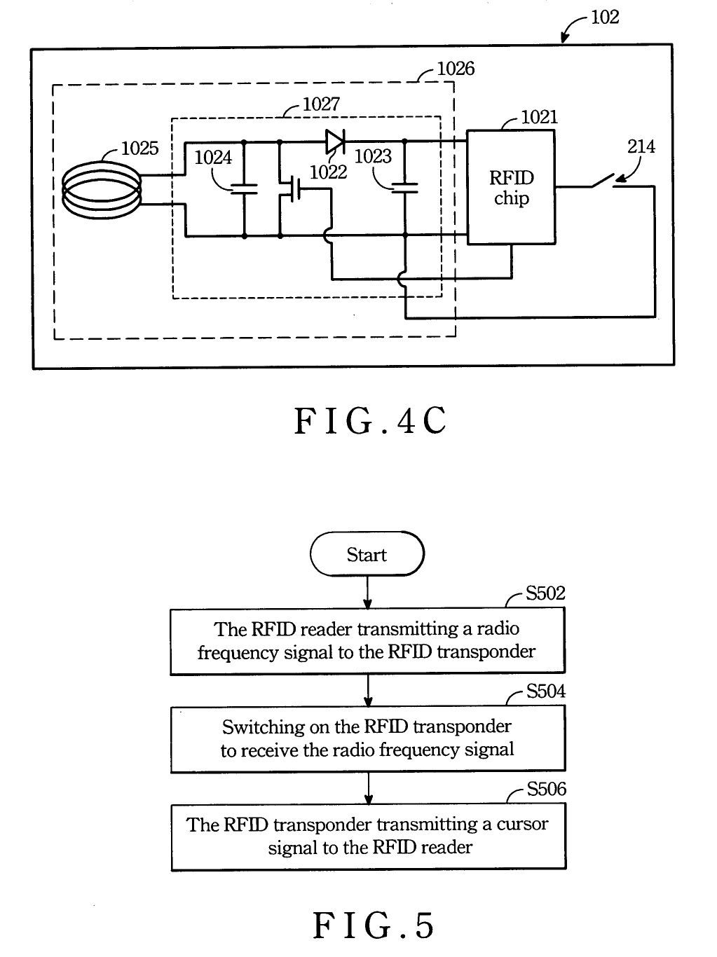

Please refer to FIG. 4A, 4B and 4C, which respectively show the different positions of the switch 214 in the RFID transponder 102. The RFID transponder 102 includes a power supply circuit 1026 and an RFID chip 1021, and the power supply circuit 1026 includes the switch 214, a diode 1022, a capacitor 1023, a capacitor 1024, and an antenna 1025. The antenna 1025 is electrically connected to the power supply circuit 1026, and the power supply circuit 1026 is electrically connected to the RFID chip 1021.

In the preferred embodiment, the RFID reader 101 keeps transmitting the radio frequency signal and the magnetic field through the antenna 1011, when the user presses the switch 214 of the cursor pointing device 201, then the RFID transponder 102 may receive the radio frequency and the magnetic field through its antenna 1025 and generates an AC that is then rectified and is filtered by the diode 1022, the capacitor 1023, and the capacitor 1024 of the voltage regulator 1027, so as to generate the DC that can make the RFID chip 1021 work, so that the RFID transponder 102 can generate the cursor signal to make the cursor on the image display device move.

In contrast, when the user releases the switch 214, then the cursor on the image display device may not move. It should be noted that the switch can be installed at different positions and still have the same function. For example, the switch 214 in FIG. 4A is connected between the antenna and the voltage regulator; the switch 214 in FIG. 4B is connected between the output of the chip 1021 and the voltage regulator 1027; the switch 214 is connected between the enable end of the chip 1021 and the voltage regulator 1027, as shown in FIG. 4C.

Please refer to FIG. 5, which is a flowchart showing the steps of the transmission method for the wireless cursor pointing device of the present invention. The cursor pointing device includes an RFID transponder that can transmit a signal to a remote RFID reader, the method includes the steps of: the RFID reader transmitting a radio frequency signal to the RFID transponder (S502); switching on the RFID transponder to receive the radio frequency signal (S504); and the RFID transponder transmitting a cursor signal to the RFID reader (S506).

Because the RFID transponder in the prior art is always “on”, in the preferred embodiment the RFID transponder must be switched off first. When the user presses the switch, the RFID transponder is switched on to receive the radio frequency signal transmitted from the RFID reader.

In step (S504), when the user presses the switch, the RFID transponder is switched on to receive the radio frequency signal. And, in step (S506), the RFID transponder transmits a cursor signal to the RFID reader, and the cursor signal is transmitted to and proceeded by the embedded controller 211, and is continuously transmitted to the CPU 212 through the chipset 213. In the end, the CPU transmits command to the cursor on the image display device 203 to make the cursor on the image display device 203 move up, down, left, and right.

The cursor pointing device of the present invention has the following advantages:

1. The volume of the wireless pointing device can be further reduced without the need for a battery;

2. No battery for recharging, and no risk of running out battery power;

3. No battery replacement is needed, less cost;

4. No battery needs to be discarded, therefore no pollution to the environment.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A wireless cursor pointing device, comprising:
an RFID transponder for sensing a radio frequency signal; and
a switch connected to the RFID transponder for switching on and off the RFID transponder;
wherein when the switch is switched on and the RFID transponder senses the radio frequency signal, the RFID transponder transmits a cursor signal.

2. The device according to claim 1, wherein the switch is a press-type switch and the RFID transponder is switched on and off by pressing and releasing the switch.

3. The device according to claim 1, wherein the RFID transponder comprises a power supply circuit and a chip, and the power supply circuit supplies power to the chip to generate the cursor signal.

4. The device according to claim 3, wherein the power supply circuit further comprises a voltage regulator for stabilizing power supplied to the chip.

5. The device according to claim 3, wherein the power supply circuit further comprises an antenna that receives the radio frequency signal and through resonance generates an AC for providing power to the power supply circuit.

6. The device according to claim 5, wherein a voltage regulator is installed between the antenna and the power supply circuit for stabilizing power supplied to the chip.

7. The device according to claim 3, wherein the power supply circuit further comprises an antenna that receives a magnetic field and generates the AC through the magnetic field to provide power to the power supply circuit.

8. The device according to claim 1, further comprising a button that is connected to the switch, and the switched is triggered when the button is pressed, and the RFID transponder generates the cursor signal.

9. The device according to claim 8, wherein the button is a direction control button, and the switch is triggered when the direction control button is pressed, and the cursor signal generated by the RFID transponder corresponds to a direction movement signal.

10. The device according to claim 8, wherein the button is a click button, and the switch is triggered when the click button is pressed, and the cursor signal generated by the RFID transponder corresponds to a click signal.

11. The device according to claim 8, wherein the button is a selection button, and the switch is triggered when the selection button is pressed, and the cursor signal generated by the RFID transponder corresponds to a selection signal.

12. An electronic system having a wireless pointing device, the system comprising:
a host;
an RFID reader connected to the host for transmitting a radio frequency signal; and
a wireless cursor pointing device, comprising
an RFID transponder for sensing the radio frequency signal transmitted from the RFID reader, and transmitting a cursor signal; and
a switch connected to the RFID transponder for switching on and off the RFID transponder,
wherein when the switch is switched on, and the RFID transponder senses the radio frequency signal, the RFID transponder transmits the cursor signal, and the host performs a command according to the cursor signal.

13. A transmission method for a wireless cursor pointing device having an RFID transponder that transmits a signal to a remote RFID reader, the method comprising the steps of:
the RFID reader transmitting a radio frequency signal to the RFID transponder;
switching on the RFID transponder to receive the radio frequency signal; and
the RFID transponder transmitting a cursor signal to the RFID reader.

14. The method according to claim 13, wherein the cursor signal is a signal of cursor movement direction.

15. The method according to claim 13, wherein the cursor signal is a click signal.

16. The method according to claim 13, wherein the RFID transponder further comprises a switch for switching on and off the RFID transponder.

17. The method according to claim 16, wherein the switch is a press-type switch and the RFID transponder is switched on and off by pressing and releasing the switch.

18. The method according to claim 13, wherein the RFID transponder comprises a power supply circuit and a chip, and the power supply circuit supplies power to the chip to generate the cursor signal.

19. The method according to claim 18, wherein the power supply circuit further comprises an antenna that receives the radio frequency signal transmitted from the RFID reader and through resonance generates an AC for providing power to the power supply circuit.

20. The method according to claim 18, wherein the power supply circuit further comprises an antenna that receives a magnetic field transmitted from the RFID reader and generates an AC for providing power to the power supply circuit.
